(19) United States
(12) Patent Application Publication
(10) Pub. No.: US 2005/0180122 A1
(43) Pub. Date: Aug. 18, 2005

(54) Electronic circuit module

(75) Inventor: Hiroshi Okabe, Tokyo (JP)

Correspondence Address: Stanley P. Fisher;Reed Smith LLP, Suite 1400, 3110 Fairview Park Drive, Falls Church, VA, 22042-4503, US

(73) Assignee: Renesas Technology Corp.

(21) Appl. No.: 11/006,551

(22) Filed: Dec. 8, 2004

(30) Foreign Application Priority Data
Feb. 17, 2004 (JP) 2004-039523

(51) Int. Cl. H05K 7/20; H05K 7/06

(52) U.S. Cl. 361/803; 361/721; 361/719; 361/749

(57) ABSTRACT

An electronic circuit module mounting a plurality of electronic circuit units in which an area thereof can be reduced without increase in the number of module substrate layers while the performance of each electronic circuit unit is not deteriorated. In the electronic circuit module mounting a plurality of electronic circuit units on a sheet of module substrate, a first electronic circuit unit which generates a large amount of heat and a second electronic circuit unit, a third electronic circuit unit which generate less amount of heat than the first electronic circuit unit are mounted. In this case, the first electronic circuit unit is mounted with the surface not forming active device to be in contact with the module substrate and the third electronic circuit unit is mounted over said second electronic circuit unit.

### CLAIM OF PRIORITY

The present application claims priority from Japanese application JP 2004-039523 filed on Feb. 17, 2004, the content of which is hereby incorporated by reference into this application.

### FIELD OF THE INVENTION

The present invention relates to an electronic circuit module in which a plurality of electronic circuit units are mounted and particularly to an electronic circuit module in which electronic circuit units which generate a large amount of heat and the other electronic circuit units are mounted.

### BACKGROUND OF THE INVENTION

As the technology to realize reduction in size of portable equipment, circuit integration of electronic circuits and formation of electronic circuit module of a plurality of electronic circuit units have been proposed. The circuit integration outstandingly excels in a degree of size reduction but it is difficult from the viewpoint of technology to accommodate devices which require different processes into an integrated circuit. Even when such circuit integration has been realized, an integrated circuit formed as the product surely becomes very expensive.

The portable equipment which is required to realize low price and size reduction is represented by a portable terminal such as a cellular phone. As an electronic circuit module to be mounted into the conventional portable terminal, the electronic circuit module in which a module substrate is formed of a thin film resin plate using polyimide has been proposed to realize reduction in thickness of module (for example, refer to the patent document 1).
[Patent Document 1] JP-A No. 127237/2001

### SUMMARY OF THE INVENTION

FIG. 6 is a plan view (component arrangement diagram) of a high frequency circuit module as an example of the electronic circuit module which the inventors of the present invention have discussed from individual viewpoints prior to proposal of the present invention. As illustrated in this figure, a power amplifier (hereinafter, abbreviated as “PA”) 11, a transmit/receive switch (hereinafter, abbreviated as “SW”) 12, a radio frequency integrated circuit (hereinafter, abbreviated as “RF-IC”) 21, a power control IC 31, and a SW control IC 32 are bare-chip mounted over a module substrate 1. Moreover, small-size surface mount components are used for a chip component 40 such as a bypass capacitor, a diplexer 41, and a low-pass filter (hereinafter, abbreviated as “LPF”) 42, while a small-size surface mount package is used for a surface acoustic wave filter (hereinafter, abbreviated as “SAW”) 44. A transmit matching network (hereinafter, abbreviated as “Tx-MN”) as a matching circuit for impedance matching with PA 11 and a receive matching network (hereinafter, abbreviated as “Rx-MN”) as a matching circuit for impedance matching with RF-IC 21 are formed of a surface mount passive device or of a multilayered wiring within the substrate using a multilayered substrate as the module substrate 1. In addition, the PA 11 on the module substrate 1 and the wiring 5 are connected with a wire 4, while the SW 12 and the wiring 6 are connected with a wire 3. The module structure disclosed in the patent document 1 described above also includes wire connecting portions.

Any of the conventional module structure disclosed in the patent document 1 and the module structure of FIG. 6 which the inventors of the present invention have discussed from individual viewpoints has realized the outstandingly small mounting area, as a result of comparison with the structure where high-frequency circuits have been formed by mounting packages over a mother board of a cellular phone, because the extra-area which has been required for the packaging has been reduced.

However, the electronic circuit module described above, including the conventional module structure disclosed in the patent document 1, has a problem because each electronic circuit unit is arranged in the plane over the module substrate. The problem is that the electronic circuit module cannot be reduced in size exceeding the total surface area of respective electronic circuit units. In other words, if the electronic circuit module is reduced in size by improving arrangement on the surface of each electronic circuit unit, the total surface area of these electronic circuit units has a limitation and further reduction in size is impossible.

Moreover, a wiring such as the module substrate wiring 5 which is used for electrical connection between the PA 11 and the power control IC 31 in the module structure of FIG. 6 is usually considered as a cause to increase the area of electronic circuit module. Therefore, when the number of wirings on the surface of module substrate is reduced by introducing a multilayered for the module substrate in order to avoid increase in the surface area, here rises a problem that the module substrate becomes expensive.

An object of the present invention is therefore to provide an electronic circuit module on which a plurality of electronic circuit units are mounted, namely to provide an electronic circuit module in which total area of module can be reduced, while the performance of each electronic circuit unit is not deteriorated and the number of module substrates is not increased.

Another object of the present invention is to provide an electronic circuit module in which a plurality of electronic circuit units are mounted, namely to provide an electronic circuit module of the surface area which is smaller than the total surface area of the electronic circuit units.

The other object of the present invention is to provide an electronic circuit module which can be easily reduced in size without use of an expensive multilayered substrate for a module substrate.

A typical invention of the inventions disclosed in this specification is as follows. Namely, the electronic circuit module of the present invention includes a module substrate, a first electronic circuit unit, a second electronic circuit unit and a third electronic circuit unit which are electrically connected respectively to the first electronic circuit unit and generate less amount of heat than the first electronic circuit unit. The first and second electronic circuit units are mounted respectively over the module substrate, while the third electronic circuit unit is mounted over the second electronic circuit unit.

The second electronic circuit unit is suitably constituted to provide larger area than the first electronic circuit unit.

The first electronic circuit unit is suitably constituted to be mounted over the module substrate so that the rear surface thereof in the opposite side of the surface where active devices are formed is in contact with the module substrate. In this case, the module substrate is suitably constituted to include thermal vias and the first electronic circuit unit is suitably constituted to radiate the heat from the rear surface through the thermal vias.

The second electronic circuit unit is suitably constituted to be mounted over the module substrate so that the surface thereof where active devices are formed is in contact with the module substrate.

The first electronic circuit unit may be constituted to be connected with the second electronic circuit unit with at least an inter-unit connection conductor and the first electronic circuit unit and the second electronic circuit unit may be constituted to be electrically connected via inter-unit connection conductors. Moreover, the first electronic circuit unit may be constituted to be connected to the third electronic circuit unit with at least an inter-unit connection conductor and the first electronic circuit unit and the third electronic circuit unit may be constituted to be electrically connected via inter-unit connection conductors. In this case, the upper surface of the first electronic circuit unit and the upper surface of the third electronic circuit unit are suitably constituted to become almost identical in the height. Moreover, the first electronic circuit unit and the module substrate are suitably constituted to provide therebetween a thermal conductive material.

The electronic circuit module of the present invention is suitably constituted to be further provided with a first auxiliary substrate and the inter-unit connection conductor is suitably constituted to be formed over the first auxiliary substrate. In this case, the first auxiliary substrate may be a deformable flexible printed circuit. In addition, the electronic circuit module may be constituted to be further provided with passive devices and these passive devices may be constituted to be mounted over the first auxiliary substrate.

At least an electronic circuit unit among the first to third electronic circuit units may be connected with a module substrate wiring formed over the module substrate with at least a unit-to-substrate connection conductor and at least an electronic circuit unit among the first to third electronic circuit units and the module substrate wiring may be constituted to be electrically connected via unit-to-substrate connection conductors.

The electronic circuit module of the present invention is suitably constituted to be further provided with the second auxiliary substrate and the unit-to-substrate connection conductor is suitably constituted to be formed over a second auxiliary substrate. In this case, the second auxiliary substrate may be a deformable flexible printed circuit. Moreover, the electronic circuit module may be further provided with at least passive devices and these passive devices may be constituted to be mounted over the second auxiliary substrate.

The electronic circuit module of the present invention may be further provided with a third auxiliary substrate and the inter-unit connection conductor and the unit-to-substrate connection conductor may be constituted to be formed over the third auxiliary substrate. In this case, the third auxiliary substrate may be a continuous flexible printed circuit. Moreover, the electronic circuit module may be further provided with at least passive devices and these passive devices may be constituted to be mounted over the third auxiliary substrate.

Moreover, the electronic circuit module of the present invention is characterized in that it is provided with a module substrate, a first electronic circuit unit, and a second electronic unit which is connected to the first electronic circuit unit and generates less amount of heat than the first electronic circuit unit, the first and second electronic circuit units are mounted on the module substrate, the first electronic circuit unit and the second electronic circuit unit are electrically connected via an inter-unit connection conductor formed over the first auxiliary substrate which is different from the module substrate, and moreover, at least any of the first and second electronic circuit units is electrically connected with a module substrate wiring formed over the module substrate via the unit-to-substrate connection conductor.

The high-frequency circuit module of the present invention is characterized in that it is provided with a module substrate, a power amplifier, a radio frequency integrated circuit which is electrically connected with the power amplifier to convert a base band signal related to a transmitting signal to a radio frequency signal, and a power control integrated circuit which is electrically connected with the power amplifier to control output power of the power amplifier on the basis of the base band signal related to the control signal, the power amplifier and radio frequency integrated circuit are respectively mounted on the module substrate and the power control integrated circuit is mounted over the radio frequency integrated circuit.

The radio frequency integrated circuit may be constituted to output the radio frequency signal to the power amplifier and the power amplifier may be constituted to amplify and output the radio frequency signal from the radio frequency integrated circuit. Moreover, the power control integrated circuit may be constituted to be formed integrally with an input-stage power amplifying transistor, the radio frequency integrated circuit to output the radio frequency signal to the power control integrated circuit, the power control integrated circuit to amplify the radio frequency signal from the radio frequency integrated circuit with the input-stage power amplifying transistor and then to output the amplified signal to the power amplifier, and the power amplifier to amplify and output the signal from the power control integrated circuit.

The high-frequency circuit module of the present invention may be further provided with a base band large scale integrated circuit for outputting the base band signal related to the transmitting signal and the base band signal related to the control signal to the radio frequency integrated circuit.

The cellular phone of the present invention is characterized to be provided with an antenna, a high-frequency circuit module electrically connected with the antenna, and a base band large scale integrated circuit electrically connected with the high-frequency circuit module and the high-frequency circuit module is characterized to be any of the profiles having the characteristics described above.

The cellular phone of the present invention is further suitably provided with an application processor electrically connected to the base band large scale integrated circuit. In this case, the application processor is suitably provided with a second module substrate, an application processor, a static random access memory (hereinafter, abbreviated as “SRAM”) which is electrically connected with the application processor to store an output of the application processor, and a flash memory which is electrically connected with the application processor to store an output of the application processor. Moreover, in this case, the application processor and SRAM may be constituted to be mounted respectively on the second module substrate and the flash memory may be constituted to be mounted over the SRAM. Moreover, the application processor and flash memory may be constituted to be mounted over the second module substrate, while the SRAM may be constituted to be mounted over the flash memory.

According to the present invention, the electronic circuit module on which a plurality of electronic circuit units are mounted ensures heat radiation property of the electronic circuit units which generate a large amount of heat and can reduce the surface area thereof by reducing the surface areas of the other electronic circuit units and moreover further reduce the surface areas thereof without increase in the number of layers of the module substrates through provision of connection conductors to electronic circuit units in the outside of the module substrate.

### BRIEF DESCRIPTION OF THE DRAWINGS

FIG. 1 is a cross-sectional view for describing a first embodiment of the electronic circuit module of the present invention;

FIG. 2 is a cross-sectional view for describing a second embodiment of the electronic circuit module of the present invention;

FIG. 3 is a cross-sectional view for describing a third embodiment of the electronic circuit module of the present invention;

FIG. 4 is a plan view (component arrangement diagram) for describing a fourth embodiment as an example of component arrangement of the electronic circuit module of the present invention;

FIG. 5 is a block diagram for describing a fifth embodiment as an example in which the electronic circuit module of the present invention is adapted to a quad-band GSM type cellular phone;

FIG. 6 is a plan view (component arrangement diagram) for describing the electronic circuit module individually discussed by the inventors of the present invention prior to the proposal thereof.

FIG. 7 is a detail circuit diagram of an RF-IC 21 in the fourth and fifth embodiments of the electronic circuit module of the present invention;

FIG. 8 is a detail circuit diagram of a PA-MMIC 11 and a power control IC 31 in the fourth and fifth embodiments of the electronic circuit module of the present invention;

FIG. 9 is a block diagram for describing a sixth embodiment as an example in which the electronic circuit module of the present invention is adapted to the quad-band GSM type cellular phone;

FIG. 10 is a cross-sectional view for describing an example of head radiation from a first electronic circuit 10 in the first embodiment of the electronic circuit module of the present invention;

FIG. 11 is a cross-sectional view for describing the example of heat radiation from the first electronic circuit 10 in the second embodiment of the electronic circuit module of the present invention; and

FIG. 12 is a cross-sectional view for describing the example of heat radiation from the first electronic circuit 10 in the third embodiment of the electronic circuit module of the present invention.

### DETAILED DESCRIPTION OF THE PREFERRED EMBODIMENTS

The preferred embodiments of the electronic circuit module of the present invention are as follows. Namely, the electronic circuit module of the present invention mounts a plurality of electronic circuit units over a sheet of module substrate. A first electronic circuit unit which generates a large amount of heat and a second electronic circuit unit and a third electronic circuit unit which generate less amount of heat than the first electronic circuit unit are mounted on the module substrate. In this case, the first electronic circuit unit is mounted in the manner that the surface not forming active devices is in contact with the module substrate and the third electronic circuit unit is laid over the second electronic circuit unit.

Owing to this constitution, heat radiation property to the module substrate from the first electronic circuit unit which generates a large amount of heat can be attained. Moreover, reduction in surface area of the electronic circuit module can be realized without deterioration of performance of each electronic circuit unit through three-dimensional mounting of the second and third electronic circuit units which do not require heat radiation property without deterioration of performance of the electronic circuit unit.

Moreover, the area required for module substrate wiring can be saved, in the electronic circuit module of the present invention, by electrically connecting the first electronic circuit unit and at least any of the second and third electronic circuit units with one or more inter-unit connector conductors. Accordingly, the module area can further be reduced without increase in the number of substrate layers.

In this case, when a thermal conductive material is inserted between the first electronic circuit unit and the module substrate to make almost identical the height of the upper surface of the first electronic circuit unit and the upper surface of the second electronic circuit unit or the third electronic circuit unit, it becomes possible, without deterioration of heat radiating property to the module substrate of the first electronic circuit unit, to form the inter-unit connection conductor to be provided between the first and second electronic circuit units or between the first and third electronic circuit units in the height identical to the module substrate surface. Accordingly, workability can be improved and thereby rise of assembling cost can also be suppressed.

In addition, when the inter-unit connection conductor is formed over a first auxiliary substrate, distance between connection conductors can be kept constant more stably than that when a plurality of connector conductors are connected individually. Accordingly, fluctuation in characteristics can be reduced and total price of substrate can be reduced more than that when the number of module substrate layers is increased because small auxiliary substrate area and less number of layers are allowed.

Moreover, when a module substrate wiring over the module substrate and at least an electronic circuit unit among the first to third electronic circuit units are electrically connected with a unit-to-substrate connection conductor provided over the second auxiliary substrate, it becomes identical to that a part of the module substrate wiring provided over the module substrate is shifted to the second auxiliary substrate of small surface area with less number of layers. As a result, the surface area of the electronic circuit module can further be reduced.

Furthermore, when at least any of the first and second auxiliary substrates is formed as a deformable flexible printed circuit, an allowable degree for fluctuation in height and displacement of each electronic circuit unit can be increased.

In addition, when the first and second auxiliary substrates are formed of a sheet of flexible printed circuit, the number of components to be mounted can be reduced and the component management cost can also be reduced.

Moreover, when one or more passive devices are mounted over at least any of the first and second auxiliary substrates, the number of components to be mounted over the module substrate can be saved. Accordingly, the electronic circuit module can be reduced in size.

Even when the third electronic circuit unit is formed within the second electronic circuit unit, the module substrate wiring can also be reduced as described above, while the heat radiation property to the module substrate of the first electronic circuit unit is maintained. Accordingly, in this case, the area of electronic circuit module can also be reduced without increase in the number of substrate layers.

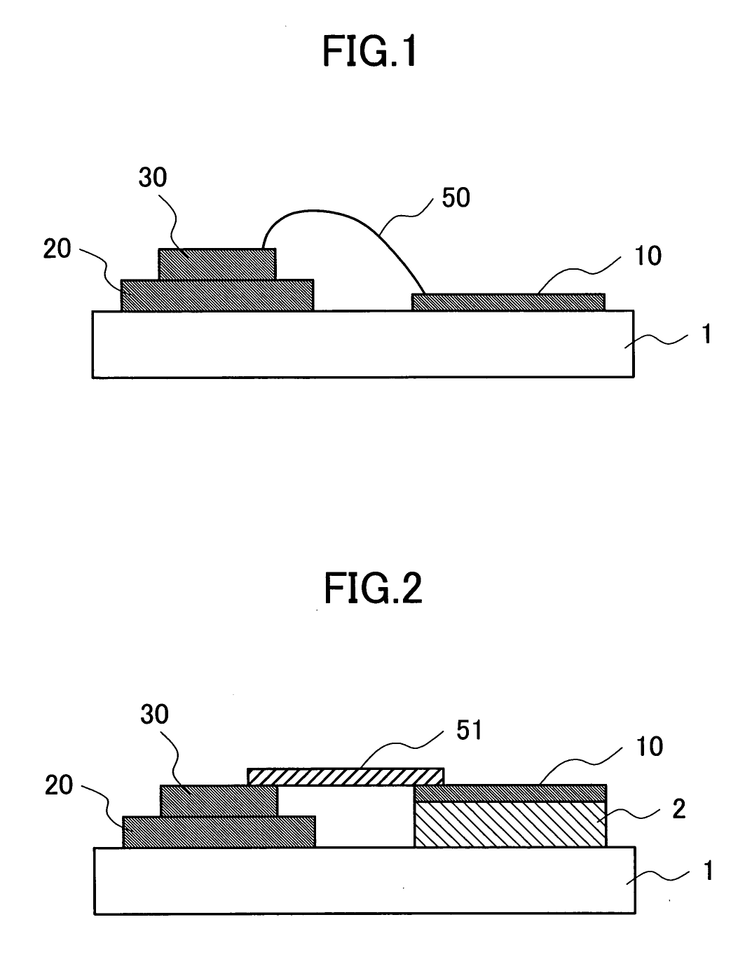

The preferred embodiments of the electronic circuit module of the present invention described above will be described in detail in the following first to sixth embodiments with reference to the accompanying drawings. The like reference numerals in FIGS. 1 to 5 and FIGS. 7 to 9 designate the like elements or similar elements corresponding with each other in the drawings.

### First Embodiment

FIG. 1 is a cross-sectional view illustrating the first embodiment of an electronic circuit module of the present invention. Over a module substrate 1, a first electronic circuit unit 10 which generates a large amount of heat is mounted with the surface (rear surface) on which active devices are not formed placed in contact with the module substrate. In regard to a second electronic circuit unit 20 and a third electronic circuit unit 30 which generate less amount of heat than the first electronic circuit unit, the second electronic circuit unit is mounted to the position different from the first electronic circuit unit over the module substrate, while the third electronic circuit unit is mounted over the second electronic circuit unit, respectively. The electronic circuit module is constituted with provision of these first to third electronic circuit units 10, 20, 30 and the module substrate 1.

The electronic circuit module is a high-frequency circuit module for GSM (Global System for Mobile Communication) cellular phone corresponding to four-frequency band (generally called the “quad-band”). Details of the quad-band cellular phone will be described in a fifth embodiment. As the module substrate, for example, a ceramic multilayer substrate of four conductor layers ensuring dielectric constant of 7.8 and thickness of 500 μm can be used.

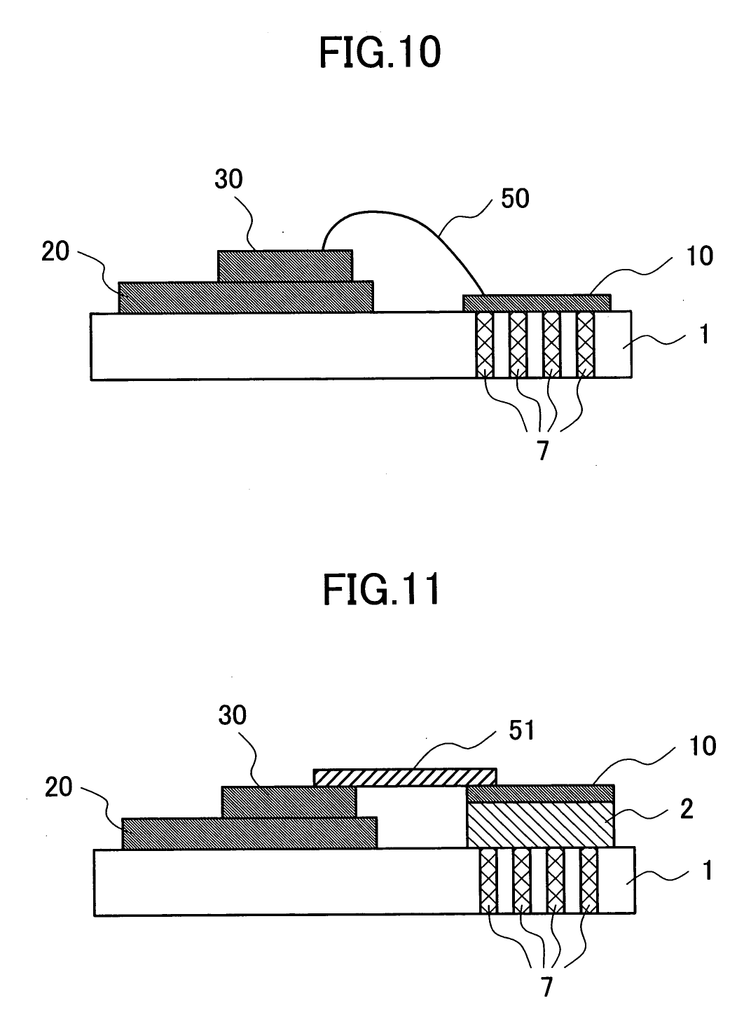

The first electronic circuit 10 can be formed of a PA-MMIC based on the GaAs-HBT, for example, in the thickness of 50 μm. In this case, heat radiation from the PA-MMIC is suitably performed, as illustrated in FIG. 10, to a mother board of the cellular phone in which the electronic circuit module of the present invention is mounted from the rear surface of the PA-MMIC through thermal vias 7 provided within the ceramic multilayer substrate.

The second electronic circuit unit 20 can be formed of an RF-IC based on the SiGe-BiCMOS, for example, in the thickness of 300 μm. In this case, the second electronic circuit unit 20 is flip-chip mounted to the module substrate 1 in such a direction that the surface (front surface) on which active devices are formed is placed in the side of module substrate. Here, as the module substrate 1, a ceramic multilayer substrate, for example, may be used.

The third electronic circuit unit 30 can be formed of a power control IC based on the CMOS, for example, in the thickness of 300 μm. In this case, this electronic circuit unit is fixed, using a bonding agent or the like, to the rear surface of the second electronic circuit unit 20, namely to the surface where active devices are not formed. As the bonding agent, an epoxy system bonding agent, for example, may be used.

Here, the RF-IC is used to form the second circuit unit 20, namely provided nearer to the module substrate 1, while the power control IC is used to form the third circuit unit 30, namely provided further from the module substrate 1. The reason is that an area of the RF-IC becomes relatively larger than that of the power control IC, particularly in the case of the quad-band cellular phone, because a comparatively complicated circuit is comprised in the RF-IC in order to process the signals in the four frequency bands. However, the electronic circuit module of the present invention is not limited to the quad-band cellular phone and can naturally be adapted to the cellular phone corresponding to three-frequency band (generally called the “triple-band”) or less-frequency band in which the area of RF-IC is relatively larger than the area of the power control IC.

In the electronic circuit module manufactured in trial, the first electronic circuit module 10 (PA-MMIC) which generates the largest amount of heat among the high-frequency circuits is never deteriorated in the performance thereof because heat radiation property has been secured. Moreover, the second electronic circuit unit 20 (RF-IC) and the third electronic circuit unit (power control IC) which are required a little for heat radiation are not deteriorated in the performance even when the three-dimensional mounting has been made because heat radiation has been a little. The power control IC used here has a function to detect a voltage generated in a reference transistor provided within the PA-MMIC and set a base potential to apply the predetermined bias current to the PA-MMIC. But, it is possible to introduce the system to read in direct the current flowing into the transistors in the PA-MMIC with a current mirror circuit. Even in this case, it is matter of course that deterioration in performance by the three-dimensional mounting is not detected because heat radiation is only a little.

Moreover, the first electronic circuit unit 10 (PA-MMIC) and the third circuit unit (power control IC) are electrically connected with a plurality of inter-unit connection conductors. As the inter-unit connecting conductor 50, a metal wire in diameter of 20 μm, for example, may be used. Accordingly, a plurality of conventional control lines provided over the module substrate can be saved.

According to this embodiment, since the second electronic circuit unit 20 and the third electronic circuit unit 30 are mounted with the three-dimensional mounting system, the first electronic circuit unit 10 and the third electronic circuit unit 30 are electrically connected with the inter-unit connection conductor 50, and the control lines over the module substrate can therefore be saved, the effect that area of the electronic circuit module is saved remarkably can be attained. In the electronic circuit module which has been manufactured in trial, area reduction amount (rate) of the electronic circuit module including the area reduction effect through the three-dimensional mounting and the reduction effect of the control lines has been about 10 percent. Moreover, when the reduction effect of the control lines corresponds to the effect in which single layer of the conductive layers is saved, when it is compared with the case of forming the same control lines as the internal layer of the module substrate 1.

As the module substrate 1, a single layer substrate of ceramic, a single layer substrate of resin, or a multilayer substrate of resin or the like can be used, in addition to a multilayer substrate of ceramic, as the module substrate 1. Even in this case, it is a matter of course that the effect of the present invention can be attained as in the case where the multilayer substrate of ceramic is used.

### Second Embodiment

FIG. 2 is a cross-sectional view illustrating a second embodiment of the electronic circuit module of the present invention. In this embodiment, the electronic circuit module and module substrate identical to that in the first embodiment are used. A thermal conductive material 2 is inserted between the first electronic circuit unit 10 (PA-MMIC) and the module substrate 1 so that the upper surface of the first electronic circuit unit 10 (PA-MMIC) becomes equal in height to the upper surface of the third electronic circuit unit 30 (power control IC). As the thermal conductive material 2, for example, molybdenum (Mo) may be used. This material ensures excellent thermal conductivity and shows a small difference in the thermal expansion coefficient against the first electronic circuit unit 10 (PA-MMIC).

Like the first embodiment, heat radiation from the first electronic circuit unit 10 (PA-MMIC) is suitably performed, as illustrated in FIG. 11, to a mother board of a cellular phone on which this electronic circuit module is mounted through thermal vias 7 provided within the ceramic multilayer substrate.

With this structure, the first electronic circuit module 10 (PA-MMIC) which generates the largest amount of heat among the high-frequency circuits is not deteriorated in the performance because the heat radiation property is attained. Moreover, the second electronic circuit unit 20 (RF-IC) and the third electronic circuit unit 30 (power control IC) which are less required for the heat radiation property are also not deteriorated in the performance because generation of heat is a little even when the three-dimensional mounting is conducted. Accordingly, reduction in size by the three-dimensional mounting can be realized as the electronic circuit module as a whole.

Moreover, in this second embodiment, an inter-unit connection conductor is formed over a first auxiliary substrate 51. As the first auxiliary substrate 51, a single layer substrate of resin, for example, in the thickness of 150 μm may be used. For respective connections of the inter-unit connection conductor and the first electronic circuit unit 10 (PA-MMIC), third electronic circuit unit 30 (power control IC), a gold bump, for example, may be used.

According to this second embodiment, the inter-unit connection conductor provided between the first electronic circuit unit 10 (PA-MMIC) and the third electronic circuit unit 30 (power control IC) can be formed in the almost identical height to the surface of module substrate 1, by inserting the thermal conductive material 2, without deterioration in the heat radiation property to the module substrate 1 of the first electronic circuit unit 10 (PA-MMIC). Therefore, it is possible to attain the effect that workability can be improved and the assembling cost can also be controlled.

Moreover, since respective distances of a plurality of inter-unit connector conductors can be kept almost constant by forming the inter-unit connection conductor over the first auxiliary substrate 5 more than the structure in which the first electronic circuit unit 10 and the third electronic circuit unit 30 including a level difference between these units are individually connected using a plurality of gold wires as the inter-unit connection conductors, it is possible to ensure the effect that fluctuation in characteristics of the electronic circuit module can be reduced. In addition, since the surface area of first auxiliary substrate 51 is small and only a single conductor layer is formed over the first auxiliary substrate 51, it is possible to attain the effect that a total price of the substrate as a whole including the module substrate and auxiliary substrate can be lowered in comparison with that when the number of layers of the ceramic multilayer substrate used as the module substrate 1 is increased only in the single layer.

### Third Embodiment

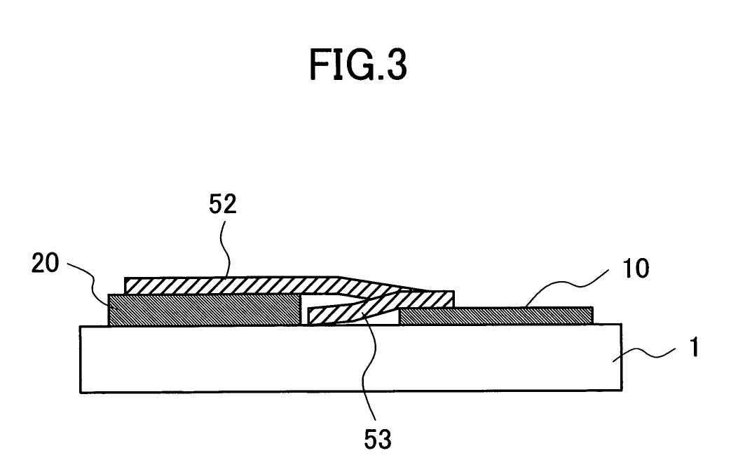

FIG. 3 is a cross-sectional view illustrating a third embodiment of the electronic circuit module of the present invention. In this third embodiment, the first electronic circuit unit 10 (PA-MMIC), second electronic circuit unit 20 (RF-IC), third electronic circuit unit 30 (power control IC), and module substrate 1 which are identical to that in the first embodiment may be used. However, the second electronic circuit unit 20, for example, may be the RF-IC with the power control function in the structure where the power control IC is integrally formed to a CMOS circuit in the RF-IC. In this case, the electronic circuit unit 20 (RF-IC with the power control function) and the first electronic circuit unit 10 (PA-MMIC) are electrically connected with an inter-unit connection conductor provided over the first auxiliary substrate 52. Moreover, the electronic circuit unit 20 (RF-IC with the power control function) may be mounted on the module substrate 1 with the surface (rear surface where the active devices are not formed) place in the direction toward the module substrate 1.

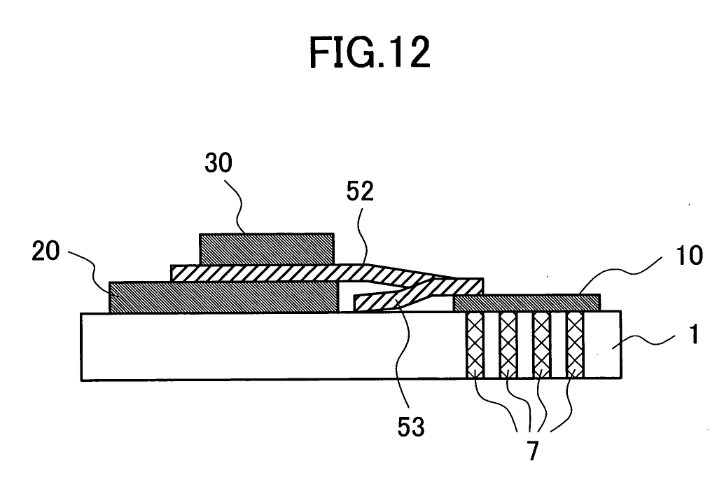

Like the first embodiment, heat radiation from the first electronic circuit unit 10 (PA-MMIC) is suitably performed, as illustrated in FIG. 12, to a mother board of a cellular phone on which this electronic circuit module is mounted via the thermal vias 7 provided in the ceramic multilayer substrate from the rear surface of the PA-MMIC.

With this structure, the first electronic circuit module 10 (PA-MMIC) which generates the largest amount of heat among the high-frequency circuits is not deteriorated in the performance because the heat radiation property is assured. Moreover, the second electronic circuit unit 20 (RF-IC) and the third electronic circuit unit 30 (power control IC) which are less required for heat radiation property are also not deteriorated in the performance because it generates less amount of heat even when the three-dimensional mounting is conducted. Therefore, reduction in size owing to the three-dimensional mounting can be realized for the electronic circuit module as a whole.

Moreover, when the third electronic circuit unit 30 (power control IC) is formed on a semiconductor chip different from that where the second electronic circuit unit (RF-IC) is formed like the first embodiment, the third electronic circuit unit 30 (power control IC) is suitably mounted on the first auxiliary substrate 52, as illustrated in FIG. 3, with the surface (front surface) forming the active devices placed toward the module substrate 1. However, the present invention is not limited thereto it is also possible to provide the structure that the third electronic circuit unit 30 (power control IC) is mounted over the second electronic circuit unit (RF-IC) with the surface (rear surface) not forming the active devices placed toward the module substrate 1 and the upper surface (front surface forming the active devices) and the first electronic circuit unit (PA-MMIC) are electrically connected with an inter-unit connection conductor provided over the first auxiliary substrate 52.

The first electronic circuit unit 10 (PA-MMIC) and a module substrate wiring on the module substrate 1 are electrically connected with a unit-to-substrate connection conductor provided over a second auxiliary substrate 53. As the second auxiliary substrate 53, a polyimide flexible substrate, for example, in the thickness of 40 μm may be used. As the first auxiliary substrate 52 for electrically connecting the RF-IC with the power control function and the first electronic circuit unit 10 (PA-MMIC), a flexible substrate, for example, having the like specifications as the second auxiliary substrate 53 may be used.

This embodiment can provide the effects that workability during manufacture of electronic circuit module can be improved and the yield of product can also be improved because connections between the electronic circuit units in different heights and connection to the module substrate wiring from the electronic circuit unit can be realized easily by using a deformable flexible substrate is used as the first and second auxiliary substrates 52 and 53. Since the first and second auxiliary substrates 52 and 53 are formed of the flexible substrates, the lengths thereof are given the allowance. Accordingly, an allowable degree for fluctuation in height and displacement of the electronic circuit units can be increased, thereby resulting in the effect that workability during manufacture of the electronic circuit module and manufacturing yield of product can further be improved.

Moreover, since the second auxiliary substrate is used, a part of the module substrate wiring which has been provided on the module substrate in the prior art can be shifted to the area on the second auxiliary substrate 53 of small area formed of less number of layers. Accordingly, the area of electronic circuit module can further be reduced in size.

In addition, owing to the structure that the power control IC is integrally formed within the RF-IC, the number of components used for manufacture of electronic circuit module can be reduced. Thereby, component management cost can also be saved. Moreover, heat radiation property to the module substrate 1 of the first electronic circuit unit 10 (PA-MMIC) can surely be attained like the first and second embodiments. Furthermore, reduction in a part of the module substrate wiring provided on the module substrate in the prior art can provide the effect that the electronic circuit module area can be reduced.

### Fourth Embodiment

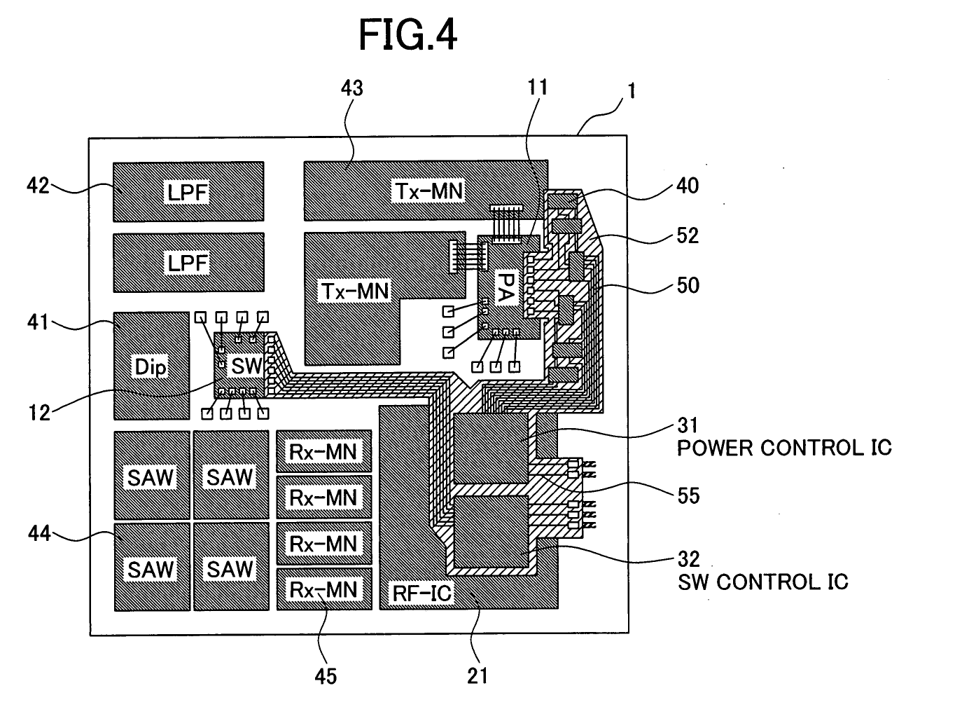

FIG. 4 is a plan view (component arrangement diagram) illustrating a fourth embodiment of the electronic circuit module of the present invention. In this embodiment, at least any of the PA-MMIC and a switch SW 12 corresponds to the first electronic circuit unit 10 in the first to third embodiments, while the RF-IC 21 to the second electronic circuit unit 20 and at least any of the power control IC 31 and a SW control IC 32 to the third electronic circuit unit 30.

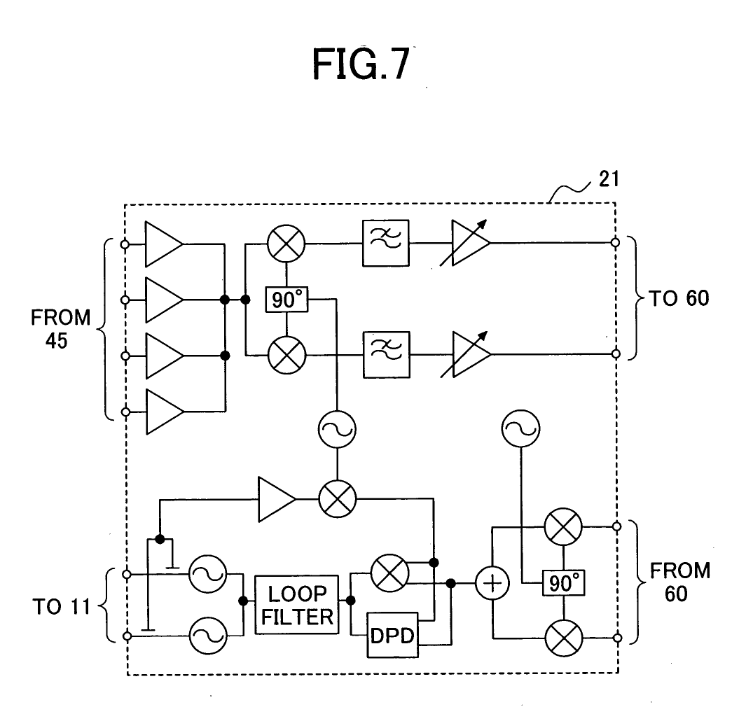

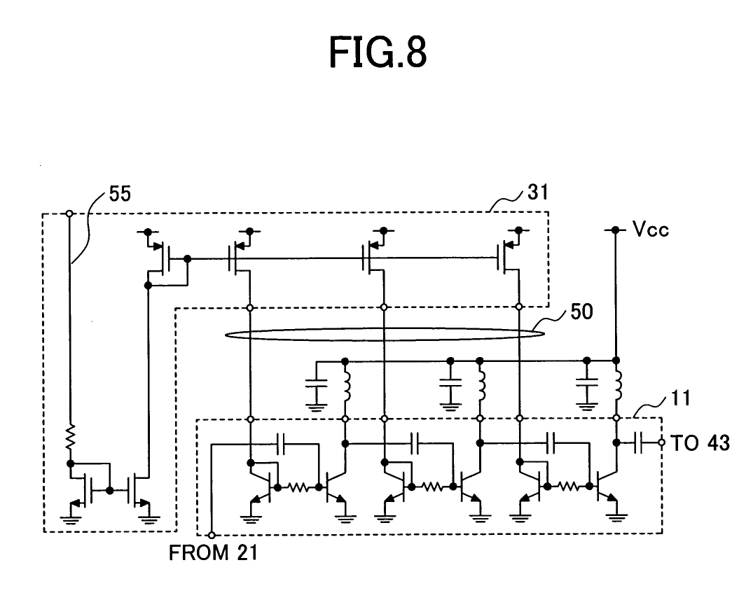

The electronic circuit module includes at least the PA-MMIC 11, RF-IC 21, and power control IC 31. A diplexer (Dip) 41, a low-pass filter (LPF) 42, a transmit matching network (Tx-MN) 43, a surface acoustic wave filter (SAW) 44, and a receive matching network (Rx-MN) 45 are also suitable included in the electronic circuit module. However, the present invention is not limited thereto and it is enough when at least any of these circuits is included in the module. As the PA-MMIC, 11, RF-IC 21, and power control IC 31, those which are identical to that in the first embodiment can be used. Particularly, the RF-IC 21 can be formed in the circuit structure illustrated in FIG. 7 (in FIG. 7, DPD is a digital phase detector). Moreover, the PA-MMIC 11 and power control IC 31 can be formed in the circuit structures, for example, illustrated in FIG. 8. The SW 12 can be formed, for example, of GaAs-pHEMT in the thickness of 50 μm. In addition, the SW control IC 32 is formed, for example, of CMOS in the thickness of 300 μm. For the module substrate 1, a multilayer resin substrate of the four conductor layers, for example, in the dielectric constant of 4.7 and thickness of 450 μm can be used.

When a multilayer resin substrate is used as the module substrate 1, heat radiation from the PA-MMIC 11 is suitably performed to a mother board of a cellular phone on which the electronic circuit module is mounted from the rear surface of the PA-MMIC 11 via the thermal vias 7 provided within the module substrate 1 (multilayer resin substrate).

In addition, since an output power from the PA-MMIC 11 controlled from the SW 12 becomes as large as 4W, even if only a small loss is generated, a large amount of heat is generated. In view of providing stable circuit operation by releasing this heat, the SW 12 is suitably mounted identical to the PA-MMIC. The thermal vias 7 provided in the module substrate 1 (multilayer resin substrate) in this embodiment can be formed, for example, with the copper plating. In this case, the thermal conductivity which is higher than that of thermal vias 7 in the ceramic multilayer substrate filled with conductive paste can be obtained.

The RF-IC 21 is flip-chip mounted with the surf ace (front surface) forming active devices for the module substrate 1 placed in the side of the module substrate 1. The power control IC 31 and SW control IC 32 are flip-chip mounted for the connection conductor on the flexible substrate 52 corresponding to the first auxiliary substrate 52 of the third embodiment and are also arranged over the RF-IC 21.

The electronic circuit module of the present invention is suitably adapted, particularly, to the high-frequency circuit module for the quad-band GSM cellular phone. This embodiment corresponds to an example of component arrangement adapted as described above. In this case, the RF-IC 21 becomes large in the area as much as the size of circuit scale. This size is enough for mounting of the power control IC 31 and SW control IC 32.

In this embodiment, as the connection conductors over the flexible substrate 52, both inter-unit connection conductor 50 and the unit-to-substrate connection conductor 55 are provided. The flexible substrate 52 in this embodiment is formed continuously of a sheet of auxiliary substrate corresponding to the first and second auxiliary substrates 52 and 53 in the third embodiment.

This embodiment can provide the effect that the component management cost can be saved because the auxiliary substrate is formed continuously with a sheet of substrate and thereby the number of components used can be reduced. Moreover, at least a passive device 40 can be mounted over the flexible substrate 52. In this case, since a part of the passive device which has been provided over the module substrate is shifted to the area over the flexible substrate 52, the effect that the number of components to be mounted over the module substrate 1 can be saved and thereby the electronic circuit module can further be reduced in size can be attained.

With various effects described above, the size of the electronic circuit module of this embodiment can be reduced by 20 percent or more without increase of the number of substrate layers in comparison with the electronic circuit module structure illustrated in FIG. 6 which has been discussed by the inventors of the present invention from the individual viewpoints prior to the proposal of the present invention.

In this fourth embodiment, as the third electronic circuit unit 30 to be mounted over the second electronic circuit unit 20 (RF-IC), at least any of the power control IC 31 and the SW control IC 32 is used. However, the present invention is not limited thereto. Namely, the present invention can also be adapted to the structure that the initial stage and the intermediate stage of the power amplifier PA or the initial stage is integrally formed into an IC together with the power control circuit and the final stage or the intermediate stage of the power amplifier and the final stage thereof is formed on a PA-MMIC are formed in place of the power control IC 31 and the identical effect can also be attained. In this case, it is enough that any of the IC where the initial stage and intermediate stage of the power amplifier or the initial stage thereof are integrated into together with the power control circuit and the SW control IC 32 is used as the third electronic circuit unit 30 and the PA-MMIC where the final stage or intermediate stage of the power amplifier and the final stage thereof are formed is used as the first electronic circuit unit 10. This structure can also be considered as the structure that the initial stage and intermediate stage of the power amplifier or the initial stage thereof are further formed within the power control IC 31. With this structure, the PA-MMIC using the GaAs substrate which is expensive in its unit area can be formed smaller than the PA-MMIC 11 of this embodiment and the power control IC using the Si substrate which is low in the price of the unit area can be formed larger, resulting in the effect that the price of the electronic circuit module can be lowered.

### Fifth Embodiment

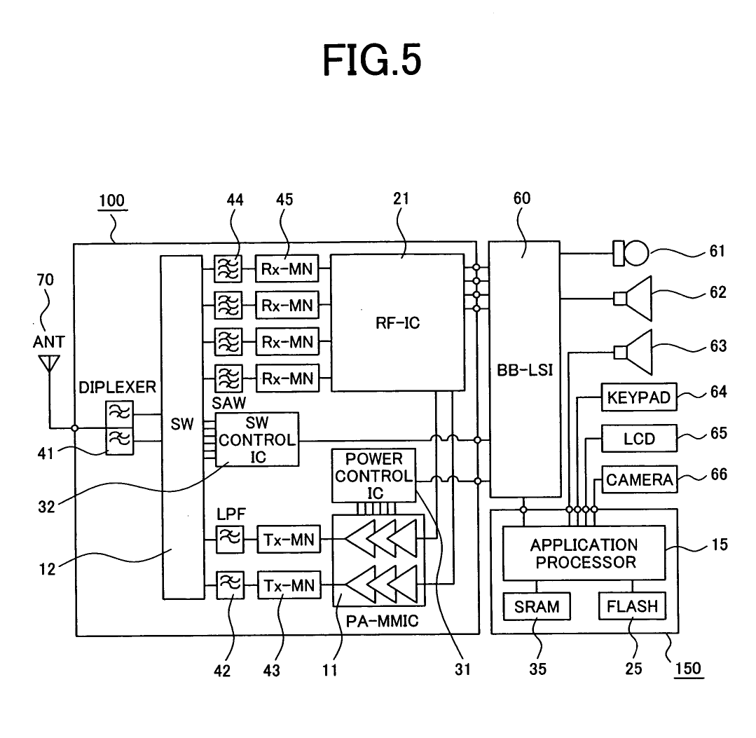

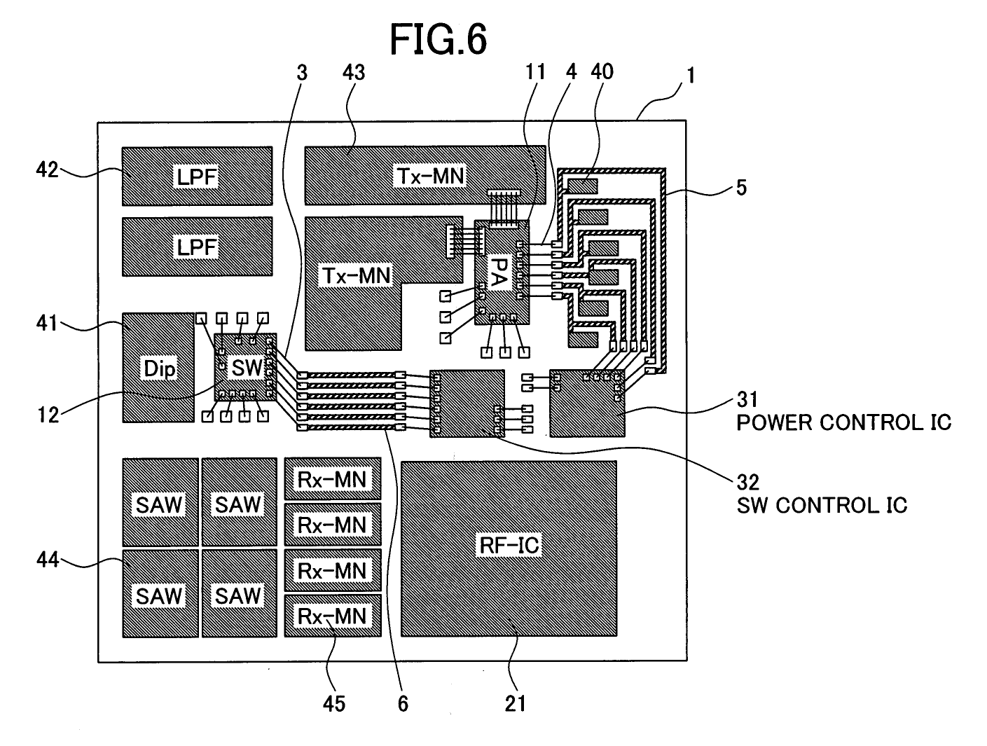

FIG. 5 illustrates a fifth embodiment as an example in which the electronic circuit module of the present invention is adapted to a structure of a cellular phone corresponding to four-frequency band (generally, called the “quad-band”) enabling common use in the Europe and the USA for the GSM which is substantially the national standard wireless communication system. Here, the common use means, in one hand, that the electronic circuit module may be used in both Europe and the USA and also means, on the other hand, the module can be supplied as the common component as the high-frequency circuit to form a cellular phone for both the cellular phone for Europe and that for the USA.

A cellular phone of this fifth embodiment is provided with a high-frequency circuit adapted to the electronic circuit module described at least in the first to fourth embodiments, a base band LSI, and an antenna.

Operations during the call in this fifth embodiment are as follows. First, during the transmission, the voice inputted from a microphone 61 is encoded and modulated with a base band large scale integrated circuit (hereinafter, referred to as “BB-LSI”) 60 and then frequency-converted to a transmitting frequency with a radio-frequency integrated circuit (hereinafter, referred to as “RF-IC”) 21, and thereafter the modulated voice signal is transmitted to a power amplifier (hereinafter, referred to as “PA”) 11.

The four frequency bands corresponding to the quad-band cellular phone are, for example, 900 MHz band for Europe (generally called the “EGSM band”), 1800 MHz band (generally called the “DCS band”) for Europe, 850 MHz (generally called the “AMPS band”) and 1900 MHz band (generally called the “PCS band”) for the USA. The PA 11 corresponds to these frequency bands with the circuits of two systems. One system amplifies the signals of GSM band and AMPS band, while the other system amplifies the DCS band and PCS band. In the PA 11, switching of the system to be used and setting of gain are conducted through the power control IC 31 from the BB-LSI 60.

The amplified signal is transmitted to a transmit/receive switch (hereinafter, referred to as “SW”) 12 via the transmit matching network (hereinafter, referred to as “Tx-MN”) 43 as a matching circuit of the PA 11 and a low-pass filter (hereinafter, referred to as “LPF”) 42 for removing the harmonics. The transmit/receive switching and selection of frequency band in the SW 12 are performed from the BB-LSI 60 via the SW control IC 32. The signal having passed the SW 12 is radiated from the antenna 70 via the diplexer 41.

Next, the signal received by the antenna 70 during the reception is distributed, in accordance with the frequency band, to any of the path for the GSM band and AMPS band or the path for the DCS band and PCS band with the diplexer 41. The distributed signal is inputted, for the frequency conversion, to the RF-IC 21 via the surface acoustic filter (hereinafter, referred to as “SAW”) 44 in accordance with the frequency band and the receive matching network (hereinafter, referred to as “Rx-MN”) 45 which is the matching circuit between the SAW 44 and the RF-IC 21. After the frequency conversion, the signal is outputted from a speaker 62 through demodulation and decoding by the BB-LSI 60. A circuit block between the ANT 70 and the BB-LSI 60 is the high-frequency circuit 100 and the electronic circuit module described for the first embodiment to the fourth embodiment can be adapted to this high-frequency circuit 100.

Particularly, the RF-IC 21 may be formed, for example, in the circuit structure illustrated in FIG. 7 and moreover the PA-MMIC 11 and power control IC 31 may be formed, for example, in the circuit structure illustrated in FIG. 8.

Moreover, cellular phones in recent years are provided with the functions for Internet communications, reproduction of music and video and for digital cameras, in addition to the telephone call functions. Accordingly, a central processing unit provided in the BB-LSI 60 has the limit in its processing capability. Therefore, the structure is suitably provided with an application processor 15 to execute such processes exclusively. A part comprising the application processor 15, an SRAM (Static Random Access Memory) 35 as the peripheral memory of the application processor, and a flash memory 25 is called the application processor means 150. In general, the application processor 15 is connected with a speaker 63 for reproducing music, a key pad 64, a liquid crystal display 65, and a camera unit 66 or the like. It is also possible here to mount the application processor means 150 and BB-LSI 60 into another module different from the high-frequency circuit 100.

A device (element) used in the high-frequency circuit 100 is different in each unit to simultaneously realize high performance and low price. For example, for the PA 11, a GaAs Hetero-Junction Bipolar Transistor (hereinafter, referred to as “HBT”) is used and therefore the PA 11 is formed as a microwave monolithic IC (hereinafter, referred to as “MMIC”) in combination with two systems.

In addition, a GaAs pseudomorphic High Electron Mobility Transistor (hereinafter, referred to as “PHEMT”) is used for the SW, an SiGe Bipolar Complementary Metal Oxide Semiconductor (hereinafter, referred to as “BiCMOS”) is used for the RF-IC, and an ordinary CMOS is used for the power control IC and SW control IC.

According to this embodiment, since reduction in size of the high-frequency circuit 100 can be realized by forming a module by adapting the electronic circuit module in any of the first to fourth embodiments into the high-frequency circuit 100, it is possible to attain the effect that a total size of a cellular phone as a whole can be reduced remarkably. Not only a total size of a cellular phone can be remarkably reduced in comparison with the high-frequency circuit 100 which has been constituted through combination of respective packages of different devices, but also a total size of a cellular phone as a whole can also be reduced remarkably in comparison with the structure where bare-chip is formed only in the plane among the high-frequency circuit 100 which has been formed by combining the bare-chips.

In this embodiment, formation of an electronic circuit module has been aimed only at the high-frequency circuit 100. However, the present invention is not limited thereto and the identical effect can also be obtained by adapting the electronic circuit module of the present invention, for example, to the application processor 150. In this case, it is enough that the application processor 15 which generates a large amount of heat is designated as the first electronic circuit unit 10 and the flash memory 25 and SRAM 35 which generate less amount of heat are designated as the second and third electronic circuit units 20 and 30. However, which one among the flash memory 25 and SRAM 35 should be place in the upper side or lower side, namely which one should be used as the third electronic circuit unit or the second electronic circuit unit may be changed in accordance with a chip size which is required for respective apparatuses. The second and third electronic circuit units may be mounted with the surface (front surface) forming active devices placed toward the module substrate 1 or with the surface (rear surface) not forming active devices placed toward the module substrate 1. In this embodiment, kind of memory has been designated to the flash memory and SRAM, but the present invention is never limited thereto. Namely, it is a matter of course that the present invention can also be adapted to the other well known kind of the memory devices.

Moreover, in this embodiment, the electronic circuit module of the present invention has been adapted only to the high-frequency circuit 100 in the block diagram of the quad-band GSM system cellular phone illustrated in FIG. 5, but the present invention is never limited thereto. That is, the electronic circuit module may be constituted to include the high-frequency circuit 100 and the BB-LSI 60. In this case, the effect of the present invention can naturally be attained.

### Sixth Embodiment

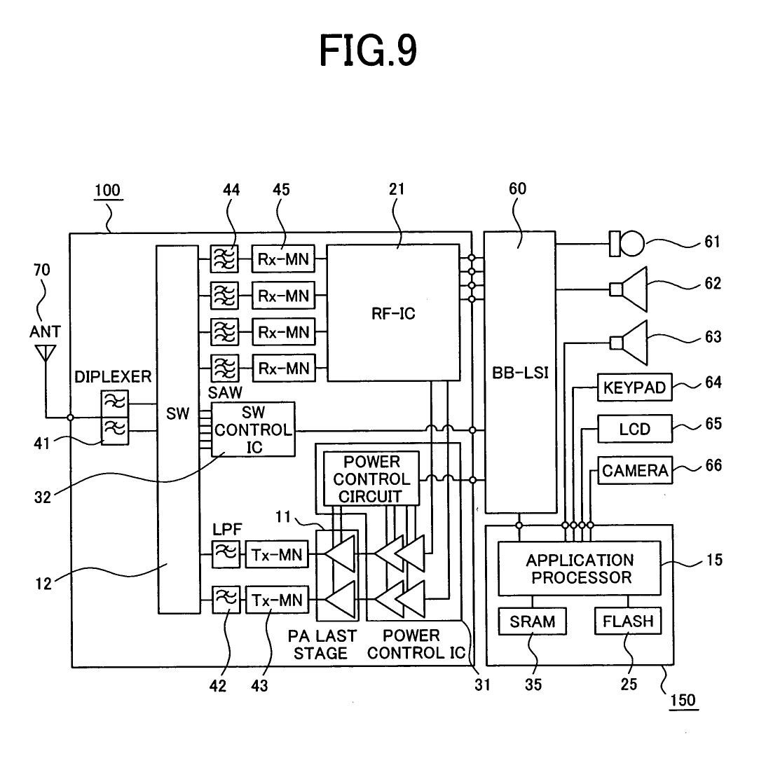

FIG. 9 is a diagram for describing a sixth embodiment as a modification example of the fifth embodiment. In the fifth embodiment, at least any of the power control IC 31 and SW control IC 32 is used as the third electronic circuit unit 30 to be mounted on the second electronic circuit unit 20 (RF-IC). However, in this sixth embodiment, the initial stage and intermediate stage of the power amplifier or the initial stage thereof has been integrated into the IC together with the power control circuit and the final stage or intermediate stage of the power amplifier and the final stage thereof is formed to only one PA-MMIC, in place of the power control IC 31. Even in this case, the effect similar to that of the fifth embodiment can be obtained. In this case, it is enough that at least any of the IC where the initial stage and intermediate stage or the initial stage of the power amplifier is integrated together the power control circuit and the SW control IC 32 is used as the third electronic circuit unit 30 and the PA-MMIC where the final stage or intermediate stage of the power amplifier and the final stage thereof is used as the first electronic circuit unit 10. This structure can also be considered as the structure where the initial stage and intermediate stage of the power amplifier or the initial stage thereof is further formed within the power control IC 31.

According to this embodiment, since the PA-MMIC using the GaAs substrate which is expensive in the unit area can be formed smaller than the PA-MMIC of this embodiment and the power control IC using the Si substrate which is cheap in the unit area can be formed larger relatively, owing to the structure described above. Accordingly, the price of the electronic circuit module can be lowered and thereby the price of the cellular phone itself can also be lowered.

1. An electronic circuit module, comprising:
a module substrate;
a first electronic circuit unit; and
a second electronic circuit unit and a third electronic circuit unit which are respectively connected electrically with said first electronic circuit unit and generate less amount of heat than said first electronic circuit unit,
wherein said first and second electronic circuit units are respectively mounted over said module substrate and said third electronic circuit unit is mounted over said second electronic circuit unit.

2. The electronic circuit module according to claim 1,
wherein said second electronic circuit module is larger in the area than said first electronic circuit unit.

3. The electronic circuit module according to claim 1,
wherein said first electronic circuit unit is mounted over said module substrate with the rear surface opposing to the front surface forming active devices to be in contact with said module substrate.

4. The electronic circuit module according to claim 3,
wherein said module substrate includes thermal vias and said first electronic circuit unit is constituted to radiate the heat from said rear surface via said thermal vias.

5. The electronic circuit module according to claim 1,
wherein said second electronic circuit module is mounted over said module substrate with the front surface forming active devices to be in contact with said module substrate.

6. The electronic circuit module according to claim 1,
wherein said first electronic circuit unit is connected with said second electronic circuit unit with at least an inter-unit connection conductor, and
wherein said first electronic circuit unit and said second electronic circuit unit are electrically connected via said inter-unit connection conductor.

7. The electronic circuit module according to claim 1,
wherein said first electronic circuit unit is electrically connected with said third electronic circuit unit with at least an inter-unit connection conductor and said first electronic circuit unit and said third electronic circuit unit are electrically connected via said inter-unit connection conductor.

8. The electronic circuit module according to claim 7,
wherein the upper surface of said first electronic circuit unit is almost identical in the height with the upper surface of said third electronic circuit unit.

9. The electronic circuit module according to claim 8,
wherein a thermal conductive material is provided between said first electronic circuit unit and said module substrate.

10. The electronic circuit module according to claim 6,
wherein said electronic circuit module is further provided with a first auxiliary substrate and said inter-unit connection conductor is formed over said first auxiliary substrate.

11. The electronic circuit module according to claim 10,
wherein said first auxiliary substrate is formed as a deformable flexible substrate.

12. The electronic circuit module according to claim 10,
wherein said electronic circuit module is further provided with at least a passive device and said passive device is mounted over said first auxiliary substrate.

13. The electronic circuit module according to claim 1,
wherein at least a unit of said first to third electronic circuit units is connected with a module substrate wiring formed over said module substrate with at least a unit-to-substrate connector conductor and at least a unit of said first to third electronic circuit unit and said module substrate wiring are electrically connected via said unit-to-substrate connection conductor.

14. The electronic circuit module according to claim 13,
wherein said electronic circuit module is further provided with a second auxiliary substrate and said unit-to-substrate connection conductor is formed over said second auxiliary substrate.

15. The electronic circuit module according to claim 14,
wherein said second auxiliary substrate is formed as a deformable flexible substrate.

16. The electronic circuit module according to claim 14,
wherein said electronic circuit module is further provided with at least a passive device and said passive device is mounted over said second auxiliary substrate.

17. The electronic circuit module according to claim 1,
wherein said first electronic circuit unit is connected with said second electronic circuit unit at least with an inter-unit connection conductor,
wherein said first electronic circuit unit and said second electronic circuit unit are electrically connected via said inter-unit connection conductor, at least a unit among said first to third electronic circuit units is connected with a module substrate wiring formed over said module substrate with at least a unit-to-substrate connection conductor, and
wherein at least a unit among said first to third electronic circuit units is electrically connected with said module substrate wiring via said unit-to-substrate connection conductor.

18. The electronic circuit module according to claim 1,
wherein said first electronic circuit unit is connected with said third electronic circuit unit with at least an inter-unit connection conductor,
wherein said first electronic circuit unit and said third electronic circuit unit are electrically connected via said inter-unit connector conductor,
wherein at least a unit among said first to third electronic circuit units is connected with said module substrate wiring formed over said module substrate with at least a unit-to-substrate connection conductor, and
wherein at least a unit among said first to third electronic circuit unit is connected electrically with said module substrate wiring via said unit-to-substrate connection conductor.

19. The electronic circuit module according to claim 17,
wherein said electronic circuit module is further provided with a third auxiliary substrate and said inter-unit connection conductor and said unit-to-substrate connection conductor are formed over said third auxiliary substrate.

20. The electronic circuit module according to claim 19,
wherein said third auxiliary substrate is formed as a deformable flexible substrate.

21. The electronic circuit module according to claim 19,
wherein said electronic circuit module is further provided with at least a passive device and said passive device is mounted over said third auxiliary substrate.

22. An electronic circuit module, comprising:
a module substrate;
a first electronic circuit unit; and
a second electronic circuit unit which is connected with said first electronic circuit unit and generates less amount of heat than said first electronic circuit unit,
wherein said first and second electronic circuit units are mounted over said module substrate,
wherein said first electronic circuit unit and said second electronic circuit unit are mounted over said module substrate,
wherein said first electronic circuit unit and said second electronic circuit unit are electrically connected via an inter-unit connector conductor formed over a first auxiliary substrate which is different from said module substrate; and
wherein at least a unit among said thirst to second electronic circuit units is electrically connected with a module substrate wiring formed over said module substrate via a unit-to-substrate connection conductor.

23. A high-frequency circuit module, comprising:
a module substrate;
a power amplifier;
a radio frequency integrated circuit which is electrically connected with said power amplifier to convert a base band signal related to a transmitting signal to a radio frequency signal; and
a power control integrated circuit which is electrically connected with said power amplifier to control an output power of said power amplifier on the basis of a base band signal related to a control signal,
wherein said power amplifier and said radio frequency integrated circuit are respectively mounted over said module substrate, and
wherein said power control integrated circuit is mounted over said radio frequency integrated circuit.

24. The high frequency circuit module according to claim 23,
wherein said radio frequency integrated circuit outputs said radio frequency signal to said power amplifier and said power amplifier amplifies and output said radio frequency signal from said radio frequency integrated circuit.

25. The high frequency circuit module according to claim 23,
wherein said power control integrated circuit is formed integrally with an input stage power amplifying transistor,
wherein said radio frequency integrated circuit outputs said radio frequency signal to said power control integrated circuit,
wherein said power control integrated circuit amplifies said radio frequency signal from said radio frequency integrated circuit with said input stage power amplifying transistor and then outputs to said power amplifier, and
wherein said power amplifier amplifies and outputs the signal from said power control integrated circuit.

26. The high frequency circuit module according to claim 23, further comprising a base band large scale integrated circuit for outputting said base band signal related to said transmitting signal and the base band signal related to said control signal to said radio frequency integrated circuit.

27. A cellular phone comprising:
an antenna;
a high frequency circuit module electrically connected with said antenna; and
a base band large scale integrated circuit which is electrically connected with said high frequency circuit module,
wherein said high frequency circuit module is provided with:
a first module substrate;
a power amplifier;
a radio frequency integrated circuit which is electrically connected with said power amplifier to convert a base band signal related to a transmitting signal to a radio frequency signal; and
a power control integrated circuit which is electrically connected with said power amplifier to control an output power of said power amplifier on the basis of a base band signal related to a control signal,
wherein said power amplifier and said radio frequency integrated circuit are respectively mounted over said first module substrate, and
wherein said power control integrated circuit is mounted over said radio frequency integrated circuit.

28. The cellular phone according to claim 27,
wherein said radio frequency integrated circuit outputs said radio frequency signal to said power amplifier and said power amplifier amplifies and outputs said radio frequency signal from said radio frequency integrated circuit.

29. The cellular phone according to claim 27,
wherein said power control integrated circuit is formed integrally with an input stage power amplifying transistor,
wherein said radio frequency integrated circuit outputs said radio frequency signal to said power control integrated circuit,
wherein said power control integrated circuit amplifies said radio frequency signal from said radio frequency integrated circuit with said input stage power amplifying transistor and outputs to said power amplifier, and
wherein said power amplifier amplifies and outputs the signal from said power control integrated circuit.

30. The cellular phone according to claim 27, further comprising an application processor means which is electrically connected with said base band large scale integrated circuit.

31. The cellular phone according to claim 30,
wherein said application processor means comprises:
a second module substrate;
an application processor;
an SRAM which is electrically connected with said application processor to store an output of said application processor; and
a flash memory which is electrically connected with said application processor to store an output of said application processor.

32. The cellular phone according to claim 31,
wherein said application processor and said SRAM are mounted respectively over said second module substrate and said flash memory is mounted over said SRAM.

33. The cellular phone according to claim 31,
wherein said application processor and said flash memory are mounted respectively over said second module substrate, and
wherein said SRAM is mounted over said flash memory.

34. The cellular phone according to claim 27,
wherein said high frequency circuit module is further provided with a base band large scale integrated circuit to output said base band signal related to said transmitting signal and said base band signal related to said control signal to said radio frequency integrated circuit.
